(19) United States
(12) Patent Application Publication
(10) Pub. No.: US 2012/0302075 A1
(43) Pub. Date: Nov. 29, 2012

(54) Signal Wiring Board and Signal Transmission Circuit

(75) Inventors: Satoshi MURAOKA, Yokohama (JP); Masayoshi YAGYU, Hannou (JP)

(73) Assignee: Hitachi, Ltd., Tokyo (JP)

(21) Appl. No.: 13/481,013

(22) Filed: May 25, 2012

(30) Foreign Application Priority Data
May 27, 2011 (JP) 2011-118749

(51) Int. Cl. H05K 1/11; H01R 12/00

(52) U.S. Cl. 439/78; 174/266

(57) ABSTRACT

The present invention maintains plugging-unplugging durability of connector pins for connecting to a signal wiring board, as well as reduces a stub length of a through hole connecting to a signal wiring. In the signal wiring board according to the present invention, a through hole connecting to the inner-layer signal wiring is formed to be shorter than the other through holes. A through hole in which a connector pin connecting to the inner-layer signal wiring is inserted is formed to have a length corresponding to a depth of the inner-layer signal wiring.

### CLAIM OF PRIORITY

The present application claims priority from Japanese patent application JP 2011-118749 filed on May 27, 2011, the content of which is hereby incorporated by reference into this application.

### BACKGROUND OF THE INVENTION

1. Field of the Invention

The present invention relates to a signal wiring board implementing signal wirings for electric signal transmission.

2. Background Art

Due to the recent high performance enhancement of electronic equipment, signal transmission speed among electronic components such as LSIs (large scale integrations) implemented in various electronic equipment has been doubling every three years. Particularly in a backplane used in a large scale data processor such as a server and a router, it has been predicted that transmission speed over 25 Gbps (gigabits per second) that is a limit of electric transmission will be required by 2013.

As signal transmission speed increases, transmission loss in a connector for connecting a PCB (printed circuit board) wiring that is a signal transmission path among LSI chips to a board becomes greater. Particularly in through holes for connecting connector pins to the PCB wiring, transmission loss increases because of reflected waves generated due to discontinuous shapes of the through holes. Such reflected waves become noise, which causes decrease of a transmissible distance or increase of bit error rate in transmission information.

The discontinuous shape of the through holes for connecting the PCB wiring to connector pins is required to be corrected into a shape causing no reflected waves, so as to reduce increase of noise.

JP Patent Application No. 2007-539262 describes a technique to reduce reflected waves in a through hole board using a back drilling technique to cut a stub that makes no contribution to signal transmission of the through hole by drilling.

JP Patent Publication (Kokai) No. 2009-158815A describes a technique to reduce a length of a stub using a laminated board.

JP Patent Publication (Kokai) No. 2008-204840A discloses a technique to minimize reflection without using through holes but using a connector to implement only connector pins connecting to signal wires on the surface of the connector.

### SUMMARY OF THE INVENTION

In the technique described in JP Patent Application No. 2007-539262, a through hole after being cut by back drilling should have a length long enough for securing a contact between a connector pin and an inner wall of the through hole when the connector pin is inserted in the through hole. Consequently, the through hole has a redundant length which becomes a stub, and thus the signal propagation characteristics are deteriorated. As a result, a signal wiring connected to such a through hole cannot be used for transmitting a high speed transmission signal, so that an additional signal wiring for a high speed transmission signal or a signal layer for installing this additional signal wiring is required, resulting in increase in cost of manufacturing the signal wiring board.

In JP Patent Application No. 2007-539262, in order to realize reduction of the stub length while maintaining a preferable contact between the connector pin and the inner wall of the through hole, it may be considered to reduce the length of the connector pin and increase a back-drill depth by the reduced length of the connector pin. Such a connector pin having a reduced length, however, deteriorates the plugging-unplugging durability of the connector pin, and thus the connector pin inserted in the through hole should be soldered in order to stably install the connector, resulting in increase in cost.

In the technique described in JP Patent Publication (Kokai) No. 2009-158815A, the through hole should have a length long enough for securing a contact between the connector pin and the inner wall of the through hole, as similar to JP Patent Application No. 2007-539262. Therefore, the same problem as in JP Patent Application No. 2007-539262 still exists even though the stub length is reduced to some extent.

In the technique described in JP Patent Publication (Kokai) No. 2008-204840A, the connector pins connecting to the signal wirings are implemented onto the surface of the board, so that the connector pins and the wirings are connected to each other only on the surface of the board, thus no through holes are required for the connection between the signal wirings and the connector pins. The signal wirings connected to the connector pins are, however, provided only on the surface of the board, so that the connector pin and the signal wiring cannot connect to each other through an inner-layer wiring, which significantly limits the wiring design.

An object of the present invention, which has been made in order to solve the mentioned problems, is to reduce a length of a stub for a through hole connecting to a signal wiring while maintaining plugging-unplugging durability of a connector pin connecting to a signal wiring board.

In the signal wiring board according to the present invention, a through hole connecting to an inner-layer signal wiring is formed to be shorter than the other through holes, and a through hole in which a connector pin connecting to the inner-layer signal wiring is inserted is formed to have a length corresponding to a depth of the inner-layer signal wiring.

The signal wiring board according to the present invention reduces the length of the through hole connecting to the inner-layer signal wiring, thereby reducing the stub length. The other through holes that do not connect to the inner-layer signal wiring are formed to be longer, so that the connector pins can be inserted deeper in the other through holes, thereby maintaining a plugging-unplugging durability.

### BRIEF DESCRIPTION OF THE DRAWINGS

FIG. 1 is a sectional side view of the signal wiring board 100 according to the first embodiment.

FIG. 2 is a view illustrating a size example of the signal wiring board 100 illustrated in FIG. 1.

FIG. 3 is a graph showing frequency characteristics of transmission loss of a through hole.

FIG. 4 is a graph showing stub-length dependent characteristics of transmission loss of a through hole.

FIG. 5 is a sectional side view of the signal wiring board 100 according to the second embodiment.

FIG. 6 is a sectional side view of the signal wiring board 100 of the prior art.

FIG. 7 is a view illustrating a size example of the signal wiring board 100 illustrated in FIG. 6.

### DETAILED DESCRIPTION OF THE PREFERRED EMBODIMENTS

Hereinafter, detailed descriptions will be provided on embodiments of the present invention with reference to the drawings. Throughout the drawings for explaining the embodiments, in principal, the same reference numerals will be given to the same elements and redundant explanation will be omitted.

### <Signal Wiring Board of Prior Art>

Hereinafter, the configuration of a signal wiring board of the prior art will be explained for the sake of the comparison to the present invention, and thereafter, the configuration of the signal wiring board according to the present invention will be explained.

FIG. 6 is a sectional side view of the signal wiring board 100 of the prior art. The signal wiring board 100 includes the signal wirings 111, 112, the through holes for signal pins 121, 122, and the through holes for ground-power supply pins 131, 132. The back drill holes 141, 142 are formed in the bottoms of the through holes for signal pins 121, 122 by back drilling.

The connector 200 is a connecting member for connecting to each through hole included in the signal wiring board 100, and includes the signal pins 211, 212 and the ground-power supply pins 221, 222.

The signal wirings 111, 112 are signal wirings for high-speed signal transmission, and are implemented as the inner-layer wirings inside the signal wiring board 100.

The through holes for signal pins 121, 122 are through holes in which the signal pins 211, 212 of the connector 200 are inserted and fixed, respectively. Each of the through holes for signal pins 121, 122 is provided with a conductor on its side wall, and the conductors are electrically connected to the signal wirings 111, 112, respectively. The signal pins 211, 212 are inserted in the through holes for signal pins 121, 122, respectively so that they are electrically connected to each other.

The through holes for ground-power supply pins 131, 132 are through holes in which the ground-power supply pins 221, 222 of the connector 200 are inserted and fixed, respectively. Each of the through holes for ground-power supply pins 131, 132 is provided with a conductor on its side wall, and the conductors are electrically connected to the ground wiring or the power supply wiring, respectively.

The back drill holes 141, 142 are so provided as to reduce the lengths of the stubs 151, 152 of the through holes for signal pins 121, 122.

An electric signal generated in the signal transmission circuit including the signal wiring board 100 and the connector 200 is input from the signal pins 211, 212, and is transmitted through the through holes for signal pins 121, 122 and the signal wirings 111, 112. Since the stubs formed in the through holes for the signal pins 121, 122 increase transmission loss due to reflected waves generated by discontinuous shapes thereof, the lengths of the stubs should be reduced so as to counter this problem.

In the configuration illustrated in FIG. 6, the signal wiring 111 seems not to be suitable for transmitting high speed transmission signal particularly because of the stub 151 having a long length.

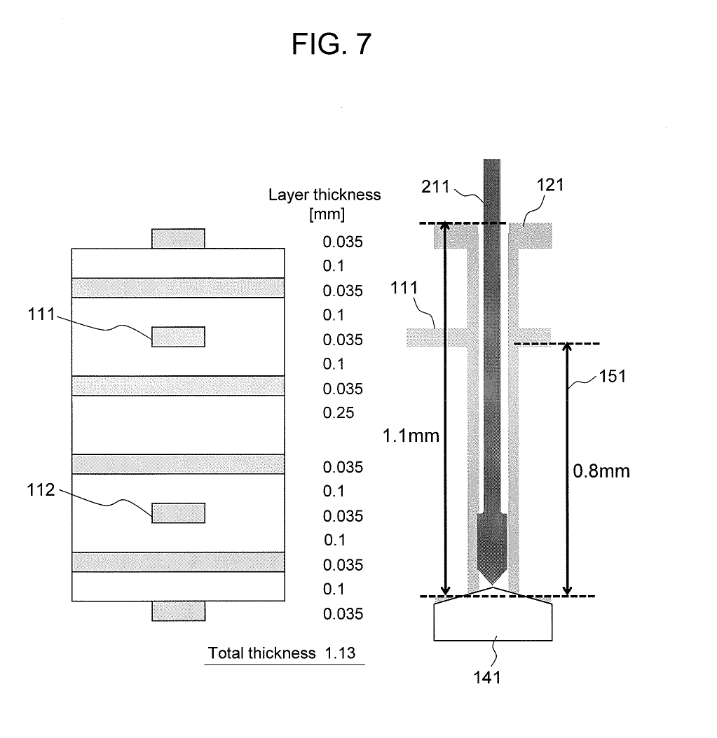

FIG. 7 is a drawing illustrating a size example of the signal wiring board 100 illustrated in FIG. 6. In this example, the total thickness of the signal wiring board 100 including the surface wiring is 1.13 mm. The stub 151 has a length of 0.8 mm, which indicates that the stub 151 has a very long length relative to the board thickness.

### First Embodiment

### Board Configuration

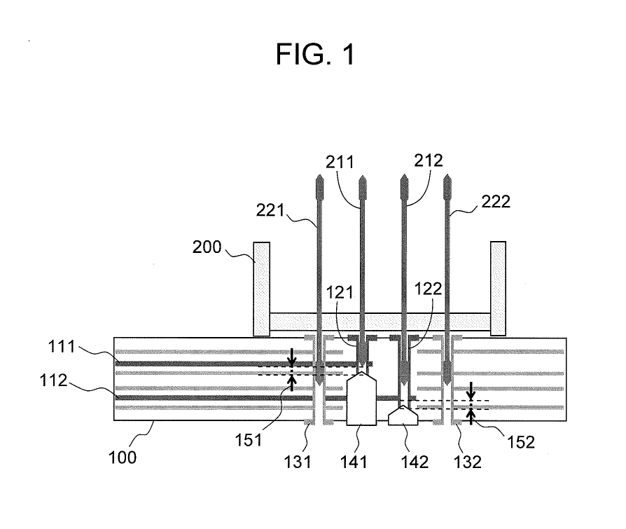

FIG. 1 is a sectional side view of the signal wiring board 100 according to the first embodiment of the present invention. The same reference numerals are given to the same elements of the signal wiring board 100 as those in FIG. 6 because the elements are the same.

As illustrated in FIG. 1, the back drill hole 141 is formed to be deeper than that in FIG. 6, and the through hole for signal pin 121 is formed to be shorter than that in FIG. 6. Such a configuration can enhance the signal transmission characteristics over the signal wiring 111 by using the stub 151 having a shorter length than that in FIG. 6. The through hole for signal pin 122 connected to the signal wiring 112 that is disposed at a deeper position, thus the stub 152 originally has a short length. Therefore, the length of the stub 152 is unnecessary to be reduced by reducing the depth of the through hole for signal pin 122.

Note that simply drilling the back drill hole 141 more deeply results in also drilling the contact portion between the signal pin 211 and the inner wall of the through hole for signal pin 121, so that the signal pin 211 and the through hole for signal pin 121 cannot come in contact with each other. To address this problem, in the first embodiment, the signal pin 211 is configured to be shorter than the other connector pins so that the signal pin 211 comes in contact with the inner wall of the through hole for signal pin 121 at an upper position of the through hole for signal pin 121.

As the result of the above configuration, the signal pin 211 is formed to be shorter than the other connector pins, and thus the through hole for signal pin 121 is also formed to be shorter than the through hole for signal pin 122.

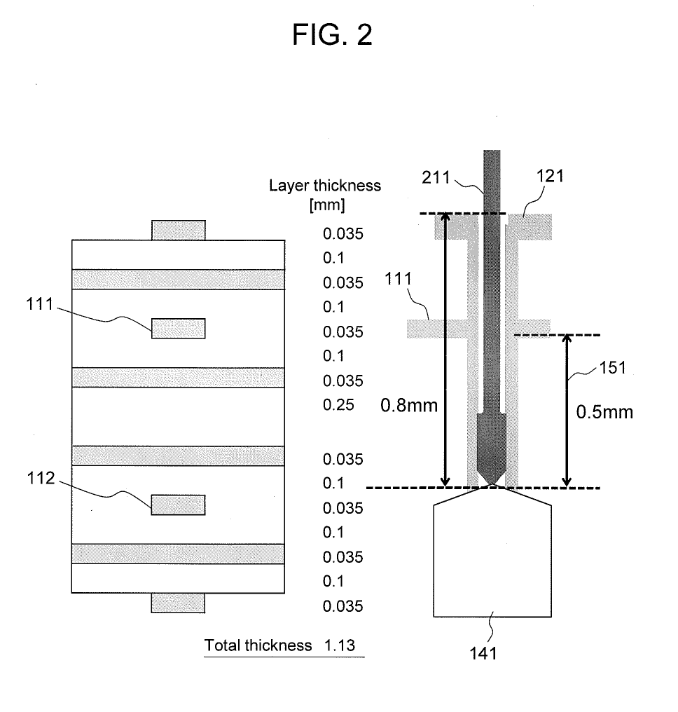

FIG. 2 is a drawing illustrating a size example of the signal wiring board 100 illustrated in FIG. 1. The signal wiring board 100 itself has the same size as that of FIG. 6. In this example, the signal pin 211 has a length of 0.8 mm, which is shorter than that in FIG. 6 and FIG. 7. The stub 151 has a length of 0.5 mm, and it is appreciated that the stub 151 has a reduced length compared to the configurations in FIG. 6 and FIG. 7.

### First Embodiment

### Transmission Characteristics

A backplane type transmission path usually has a configuration of connecting two print boards to a backplane board and transmitting a signal through two connectors. Hence, one transmission path includes four connection portions at which the connectors are connected to the signal wiring boards.

According to the high speed transmission standard IEEE 802.3ap (10 Gbps), transmission loss of a transmission pass is supposed to be 25 dB as a median. Assuming that the transmission loss due to the signal wiring and the connecter itself accounts for approximately 20 dB of 25 dB, it is expected that approximately 6 dB is assigned to the through holes connected to the signal pins. In this case, the transmission loss should be reduced to 1.5 dB or less per through hole.

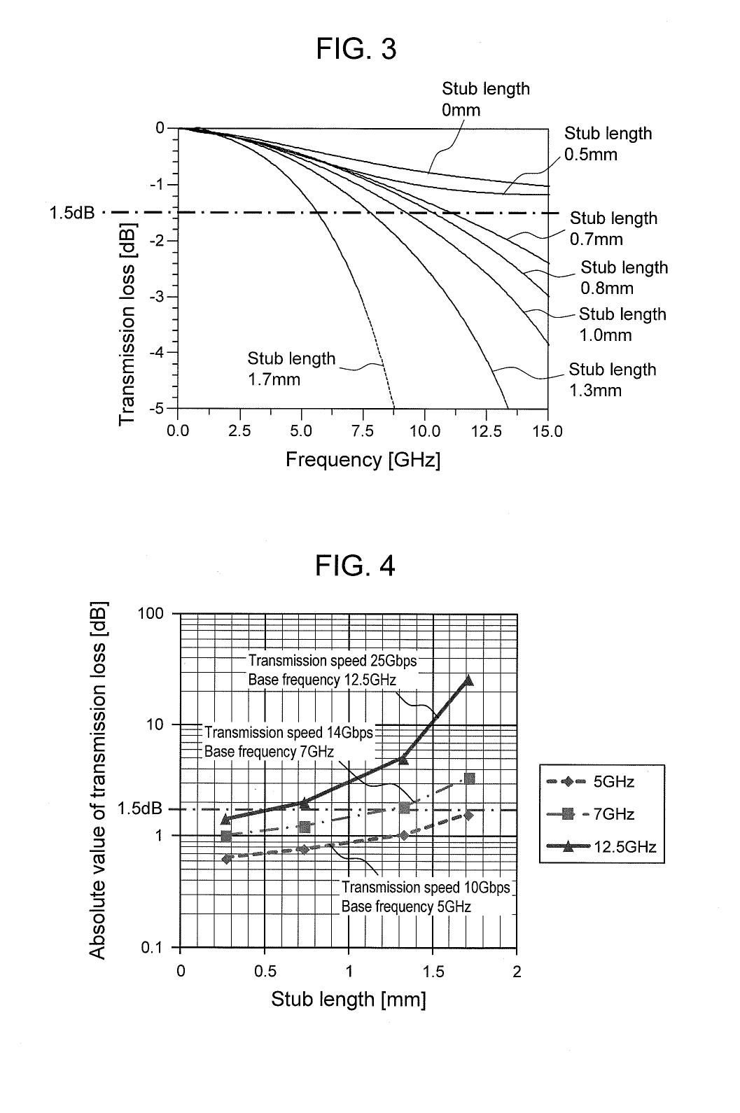

FIG. 3 graphically illustrates the frequency characteristics of the transmission loss of the through hole. The transmission loss of the through hole becomes greater as the frequency becomes higher, and also becomes greater as the length of the stub becomes longer.

FIG. 4 graphically illustrates the stub-length dependent characteristics of the transmission loss of the through hole. The base frequency of data at the transmission speed of 10 Gbps is 5 GHz, the base frequency of data at the transmission speed of 14 Gbps is 7 GHz, and the base frequency of data at the transmission speed of 25 Gbps is 12.5 GHz. As the base frequency of data becomes higher, the stub-length dependent characteristics of the transmission loss become increased drastically.

According to the graph of FIG. 4, in order to keep the transmission loss of the through hole to 1.5 dB or less, the stub length should be limited to 1.7 mm or less at the transmission speed of 10 Gbps, the stub length should be limited to 1.2 mm or less at the transmission speed of 14 Gbps, and the stub length should be limited to 0.5 mm or less at the transmission speed of 25 Gbps.

In the first embodiment, in order to set the stub length to 0.5 mm or less at the transmission speed of 25 Gbps, the length of the signal pin 211 is set to 0.8 mm, and the back drill hole 141 is drilled over the through hole for signal pin 121 so as to reduce the length of the stub 151 to 0.5 mm.

The length of the signal pin 212 connecting to the through hole for signal pin 122 connecting to the signal wiring 112 is unnecessary to be reduced because the length of the stub 152 for the signal pin 212 is 0.27 mm or less, which satisfies the condition of the stub length of 0.5 mm or less required at the transmission speed of 25 Gbps.

On the other hand, if the length of the signal pin 211 is reduced, the other connector pins are usually supposed to have the same length as the reduced length of the signal pin 211. Specifically, each length of the signal pin 212 and the ground-power supply pins 221, 222 is supposed to be reduced to the same length as that of the signal pin 211.

However, the reduction of the lengths of the connector pins deteriorates plugging-unplugging durability of the connector 200, which consequently limits the plugging-unplugging cycles. This problem can be solved by soldering or screwing the connector, or using a thicker pin to secure the plugging-unplugging durability, but this causes increase in assembly man-hours and increases manufacturing cost. Particularly in a product in which the connector 200 is fixed by mechanically fitting the connector pins into the through holes, the above configuration unfavorably loses simplicity of the assembly process.

To address such a problem, the first embodiment employs a configuration to reduce only the length of the signal pin connecting to a through hole for which the stub length is required to be reduced, and maintain the lengths of the other signal pins and the ground-power supply pin to have the same length as the conventional length. This configuration can maintain the plugging-unplugging durability of the connector 200 by using the connector pins whose lengths cannot be reduced, as well as realizing reduction of the stub length.

### First Embodiment

### Conclusion

As described above, in the signal wiring board 100 according to the first embodiment, the through hole for signal pin 121 connecting to the signal wiring 111 is formed to be shorter than the other through holes. The through hole for signal pin 121 has a length in correspondence to the depth of the signal wiring 111, and the signal pin 211 is formed to be shorter than the other connector pins. With this configuration, the signal transmission characteristics over the signal wiring 111 can be maintained to be preferable. Each of the other connector pins has a longer length than that of the signal pin 211, thereby maintaining the plugging-unplugging durability as well as securing movable range in the lateral direction of the connector 200.

The signal wiring board 100 according to the first embodiment can transmit the high speed transmission signal using the signal wiring 111, which eliminates necessity of providing an additional signal wiring for transmitting the high speed transmission signal or an additional signal wiring layer for installing this signal wiring, thereby realizing the low-cost signal wiring board 100 that achieves cost reduction.

### Second Embodiment

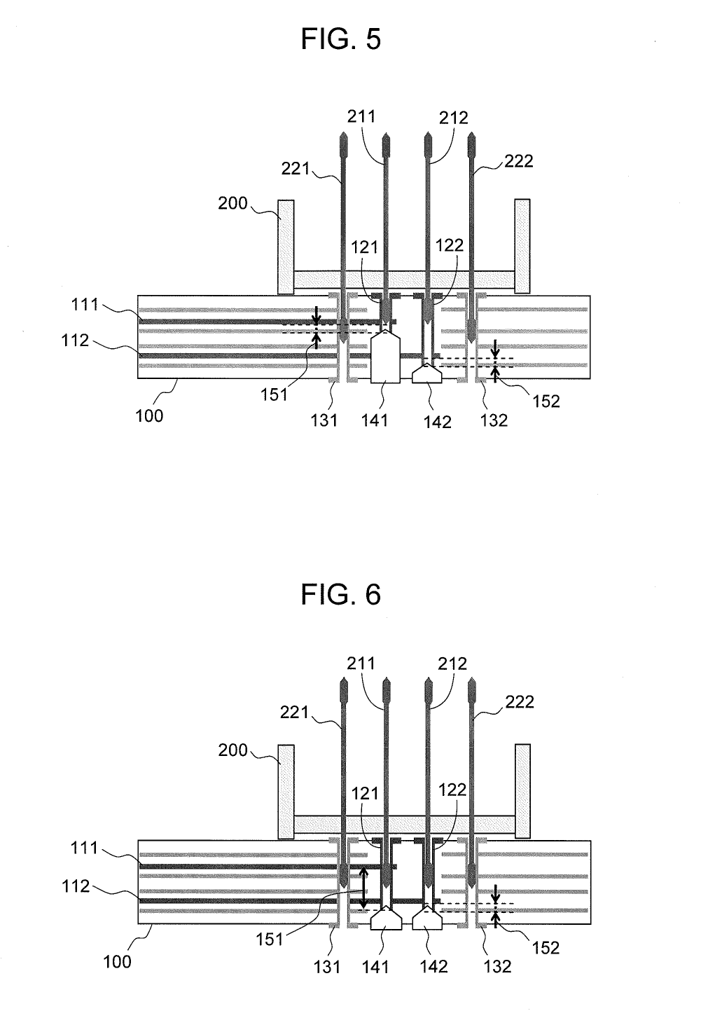

FIG. 5 is a sectional side view of the signal wiring board 100 according to the second embodiment of the present invention. In the first embodiment, descriptions have been provided on the example of configuring only the signal pin 211 to be shorter, but such a configuration requires each signal pin of the connector 200 to be processed individually, which is not preferable in the light of the manufacturing cost. In the second embodiment, all the signal pins are formed to have the same length. Specifically, the other connector pins are configured to have the same length as the shorter length of the signal pin 211.

The through hole for signal pin 122 is connected to the signal wiring 112 at a deeper position in the signal wiring board 100, so that the stub 152 does not become longer even if the signal pin 212 is formed to be shorter. Accordingly, the second embodiment can achieve the same effect as that of the first embodiment, and this configuration is advantageous in the light of the manufacturing cost of the connector 200.

### Third Embodiment

In the first and second embodiments, descriptions have been provided on the example of reducing the stub lengths by the back drill holes 141, 142 after forming the through holes extending through the signal wiring board 100, but the method of reducing the stub length is not limited to this. Other examples of manufacturing the signal wiring board 100 having a reduced stub length may include the following methods.

### (Method 1 of Reducing Stub Length)

Signal wiring boards having via-holes and inner-layer wirings may be laminated so as to produce a multilayered wiring board. If the boards are laminated such that positions of through holes of each board are aligned with each other, through holes extending through the boards can be formed. If the boards are laminated such that the positions of through holes of each board disagree with each other, the signal wiring board having via-holes extending to intermediate positions in the laminated board can be obtained. Adjustment of the lengths of the through holes themselves as well as the position at which the boards are laminated, as described above, can realize the signal wiring board 100 having the configuration similar to the first and second embodiments.

### (Method 2 of Reducing Stub Length)

A signal wiring board having via-holes and inner-layer wirings is prepared in advance, and a wiring layer is laminated on the prepared signal wiring board so as to produce a multilayered wiring board. The through holes can be formed by using laser machining or photo lithography.

Specific descriptions have been provided on the present invention made by the inventors based on the embodiments, but the present invention is not limited to the descriptions of the embodiments, and various modification and alternations can be made without departing from the spirit and scope of the invention.

### DESCRIPTION OF SYMBOLS

100: Signal wiring board
111,112: Signal wirings
121,122: Through holes for signal pins
131,132: Through holes for ground-power supply pins
141,142: Back drill holes
151,152: Stubs
200: connector
211,212: Signal pins
221,222: Ground-power supply pins

What is claimed is:

1. A signal wiring board implementing signal wirings for transmitting an electric signal,
the signal wiring board comprising:
plural through holes extending in a depth direction of the signal wiring board; and
signal wirings disposed in the signal wiring board, the signal wirings being connected to one of the plural through holes, wherein
the through hole connected to the signal wirings has shorter lengths than lengths of the other through holes,
the signal wirings comprise:
a first signal wiring; and
a second signal wiring disposed at a deeper position than that of the first signal wiring, and
the through hole connected to the first signal wiring has a shorter length than a length of the through hole connected to the second signal wiring.

2. The signal wiring board according to claim 1, wherein
the through holes other than the through holes connected to the signal wirings are connected to a power supply wiring or a ground wiring.

3. The signal wiring board according to claim 1, wherein
the through holes connected to the signal wirings are formed such that after each of the through holes is formed as a through via-hole, a length thereof is reduced by back drilling so as to have a shorter length than the lengths of the other through holes.

4. The signal wiring board according to claim 1, wherein
the signal wiring board is formed by laminating boards in which the signal wirings and the through holes are formed in advance.

5. The signal wiring board according to claim 1, wherein
the signal wiring board is formed by stacking a wiring layer on a board in which the signal wirings and the through holes are formed in advance.

6. A signal transmission circuit comprising:
the signal wiring board according to claim 1; and
a connector including connector pins for connecting to the through holes, wherein the connector pins comprise:
a signal pin for transmitting an electric signal; and
a ground-power supply pin for connecting to a ground or a power supply, and the signal pin is configured to be fit into the through hole connected to the signal wiring.

7. The signal transmission circuit according to claim 6, further comprising:
a plurality of the signal pins, each of which has a same length, wherein
each of the signal pins is configured to be fit into the through hole having a shortest length of the through holes.
